(19) United States
(12) Patent Application Publication
(10) Pub. No.: US 2012/0212114 A1
(43) Pub. Date: Aug. 23, 2012

(54) FIXING UNIT, COMPUTER ACCESSORY DEVICE MOUNTING APPARATUS AND AN ELECTRONIC DEVICE HAVING THE SAME

(75) Inventors: YOU QIANG WEI, GUANGZHOU (CN); GANG CHENG, GUANGZHOU (CN); CHUAN-CHIEH TSENG, NEW TAIPEI CITY (TW)

(73) Assignees: LITE-ON TECHNOLOGY CORPORATION, TAIPEI CITY (TW); SILITEK ELECTRONIC (GUANGZHOU) CO., LTD., GUANGZHOU (CN)

(21) Appl. No.: 13/231,939

(22) Filed: Sep. 13, 2011

(30) Foreign Application Priority Data
Feb. 18, 2011 (CN) 201120044274.2

(51) Int. Cl. H05K 5/02

(52) U.S. Cl. 312/223.2; 403/321

(57) ABSTRACT

A fixing unit includes a fixing plate and a bolting member. The fixing plate including a front surface and a rear surface has a holding portion and a locking structure. The bolting member is movably assembled on the fixing plate. The bolting member includes a main segment, an extension segment and a protruding segment sequentially defined thereon. The main segment and the extension segment have a first flanged structure therebetween. The extension segment inserts into the holding portion of the fixing plate. When the bolting member is secured to the fixing plate, the protruding segment of the bolting member exposes form the front surface.

### BACKGROUND OF THE INVENTION

1. Field of the Invention

The present invention relates to a fixing unit, a computer accessory device mounting apparatus and an electronic device having the same. In particular, the present invention relates to a fixing unit that is applied to fixing a computer accessory device in an electronic device in a screw-less and tool-less manner.

2. Description of Related Art

With the technology improvement, modern computers are developed for high processing rate, multi-function and small size. Particularly, electronic data storage media, such as hard disk drives, floppy disks, disk storage drive, optical disk drives, electronic card readers or magnetic tape drives may be used.

Traditionally, the computer accessory devices (such as disk drives) are mounted on the disk carrier by screws. The combination of the disk drive and the carrier is further mounted inside a computer casing by screws. Alternatively, a disk drive may be guided and held by a pair of mounting tracks arranged on the frame of a computer casing and slid along the tracks into a correct location, the disk drive can then be secured in the computer casing by screws. When users want to change or upgrade the mounted disk drive, it is necessary to release the screws for drawing the mounted disk drive out of the computer casing. In other words, while assembling or disassembling the disk drive, users have to put the screws on or loosen the screws. On the other hand, the screws are so small that they are easily lost in the process of assembling or disassembling the disk drive. Additionally, as the number of the screws is large and the size thereof is small, some of the screws may be left inside the computer casing, contact the circuit board and cause short circuit. Therefore, the lost issue of the screws results in the non-convenience for the users. Furthermore, tools, such as screw drives, are necessary for users to tighten or loose the screws. Such assembling/disassembling technique is troublesome and time consuming.

Therefore, it is necessary to propose a fixing unit and a computer accessory device mounting apparatus for fixing a computer accessory device in an electronic device to overcome the above-mentioned problems, wherein the computer accessory device can be easily fixed or detached.

### SUMMARY OF THE INVENTION

One particular aspect of the present invention is to provide a fixing unit which can be mounted on a computer accessory device mounting apparatus, an electronic device or any other similar objects. By the fixing unit, the computer accessory device, such as storage device or disk drive can be efficiently assembled by a screw-less/tool-less manner. Therefore, the non-convenience and un-efficiency of using screws and tools in tradition may be solved.

The instant disclosure provides a fixing unit includes a fixing plate and a bolting member. The fixing plate has a front surface and a rear surface opposite to the front surface. The fixing plate has a holding portion and a locking structure formed on the rear surface thereof. The bolting member is movably assembled on the rear surface of the fixing plate. The bolting member includes a main segment, an extension segment and a protruding segment connected to the extension segment. The main segment and the extension segment have a first flanged structure there-between and the first flanged structure corresponds to the locking structure. The extension segment inserts into the holding portion of the fixing plate. When the bolting member is secured to the fixing plate, the protruding segment of the bolting member exposes from the front surface.

The instant disclosure provides a computer accessory device mounting apparatus for fixing the computer accessory device, such as storage device or disk drive, having at least one retaining hole on a side wall thereof. The computer accessory device mounting apparatus includes a computer accessory device mounting member and a fixing unit fixed on the computer accessory device mounting member. The computer accessory device mounting member has an insertion hole on a side edge thereof and the insertion hole corresponds to the retaining hole of the computer accessory device. The fixing plate has a front surface and a rear surface opposite to the front surface. The fixing plate has a holding portion and a locking structure formed on the rear surface thereof. The bolting member is movably assembled on the rear surface of the fixing plate. The bolting member includes a main segment, an extension segment and a protruding segment connected to the extension segment. The main segment and the extension segment have a first flanged structure there-between and the first flanged structure corresponds to the locking structure. The extension segment inserts into the holding portion of the fixing plate. When the bolting member is secured to the fixing plate, the protruding segment of the bolting member exposes from the front surface and corresponds to the retaining hole of the computer accessory device.

The instant disclosure provides an electronic device which includes a casing and at least one computer accessory device mounting apparatus. The casing has an opening communicating with the interior of the casing. The computer accessory device mounting apparatus includes a computer accessory device mounting member and a fixing unit fixed on the computer accessory device mounting member. The computer accessory device mounting member has an insertion hole on a side edge thereof and the insertion hole corresponds to the retaining hole of the computer accessory device. The fixing plate has a front surface and a rear surface opposite to the front surface. The fixing plate has a holding portion and a locking structure formed on the rear surface thereof. The bolting member is movably assembled on the rear surface of the fixing plate. The bolting member includes a main segment, an extension segment and a protruding segment connected to the extension segment. The main segment and the extension segment have a first flanged structure therebetween and the first flanged structure corresponds to the locking structure. The extension segment inserts into the holding portion of the fixing plate. When the bolting member is secured to the fixing plate, the protruding segment of the bolting member exposes from the front surface and corresponds to the retaining hole of the computer accessory device.

The bolting member of the fixing unit is movably assembled on the fixing plate; therefore, users may force to push in or pull out the bolting member for fixing/releasing the computer accessory device. As a result, the requirement of screw-less and tool-less of assembling the computer accessory device is met. On the other hand, a second flange structured is further formed between the extension segment and protruding segment in the second embodiment. The second flanged structure and the holding portion are corresponding to each other so that the bolting member is difficult to release from the fixing plate after the second flanged structure passed through the holding portion.

For further understanding of the present invention, reference is made to the following detailed description illustrating the embodiments and examples of the present invention. The description is for illustrative purpose only and is not intended to limit the scope of the claim.

### BRIEF DESCRIPTION OF THE DRAWINGS

FIG. 1 shows the fixing plate of the fixing unit in the first embodiment of the instant disclosure;

FIG. 1A shows the bolting member of the fixing unit in the first embodiment of the instant disclosure;

FIG. 2 is an explode diagram of the fixing unit in the first embodiment of the instant disclosure;

FIG. 2A is an perspective diagram of the combination of the fixing plate and the bolting member in FIG. 2;

FIG. 2B is another perspective diagram of the combination of the fixing plate and the bolting member in FIG. 2;

FIG. 3 is an explode diagram of the computer accessory device mounting member and the fixing unit in the first embodiment of the instant disclosure;

FIG. 3A is a perspective diagram of the combination of the computer accessory device mounting member and the fixing unit in FIG. 3;

FIG. 4 shows the electronic device having the combination of FIG. 3A;

FIG. 4A shows an enlarged top sectional view of the computer accessory device mounting apparatus and the computer accessory device in an unlocked position;

FIG. 4B shows the an enlarged top sectional view of the computer accessory device mounting apparatus and the computer accessory device in a locked position;

FIG. 5 shows the fixing plate of the fixing unit in another embodiment of the instant disclosure;

FIG. 6A shows the fixing plate of the fixing unit in the second embodiment of the instant disclosure;

FIG. 6B shows the bolting member of the fixing unit in the second embodiment of the instant disclosure;

FIG. 6C is an perspective diagram of the combination of the fixing plate and the bolting member in FIGS. 6A and 6B;

FIG. 6D shows an enlarged top view of the computer accessory device mounting member having the fixing unit of FIG. 6C and the computer accessory device in an unlocked position;

FIG. 6E shows an enlarged top view of the computer accessory device mounting member having the fixing unit of FIG. 6C and the computer accessory device in a locked position.

### DETAILED DESCRIPTION OF THE PREFERRED EMBODIMENTS

The fixing unit particularly suitable for fixing a computer accessory device onto a casing of an electronic device, such as, but not limited to, a computer. The computer accessory device may refer to storage device, such as, but is not limited to, a floppy disk drive (FDD), a hard disk drive (HDD), an optical disk drive (ODD), an electric card reader or other disk storage device. Particularly, embodiments of the present invention provide a tool-less/screw-less retaining mechanism for securely fixing a computer accessory device (such as a disk drive) onto the frame of a computer casing, thus greatly improving the assembling/disassembling efficiency. Moreover, comparing with the traditional mounting mechanisms that require numerous nuts and bolts, the instantly disclosed fixing unit includes only two major components securely engageable with each other. Therefore, a user of the instantly disclosed fixing unit will not have to worry about losing/dropping screws/bolts during the assembling/dissembling process. The accompanying drawings are merely for reference and illustration, and are not intended to limit the present invention.

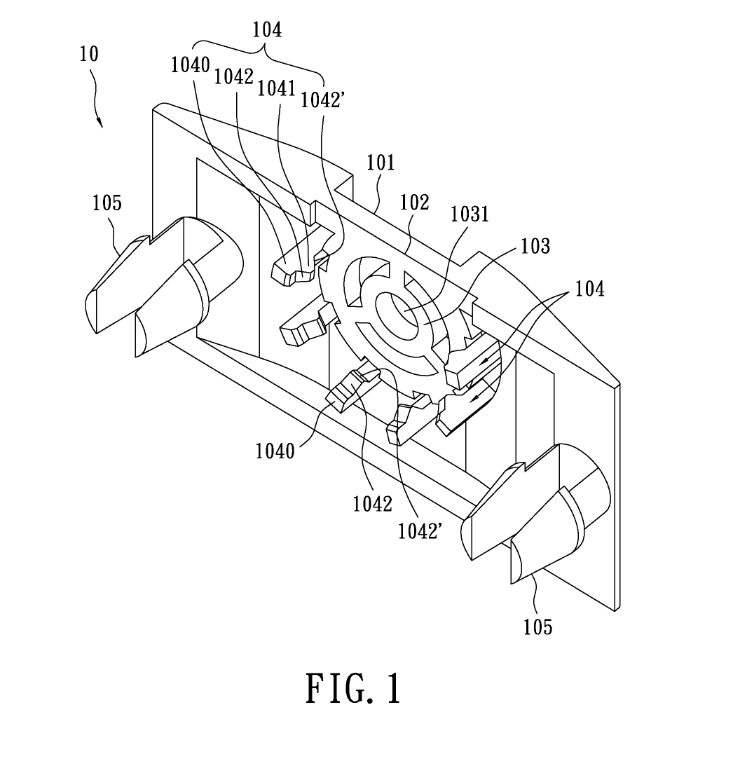

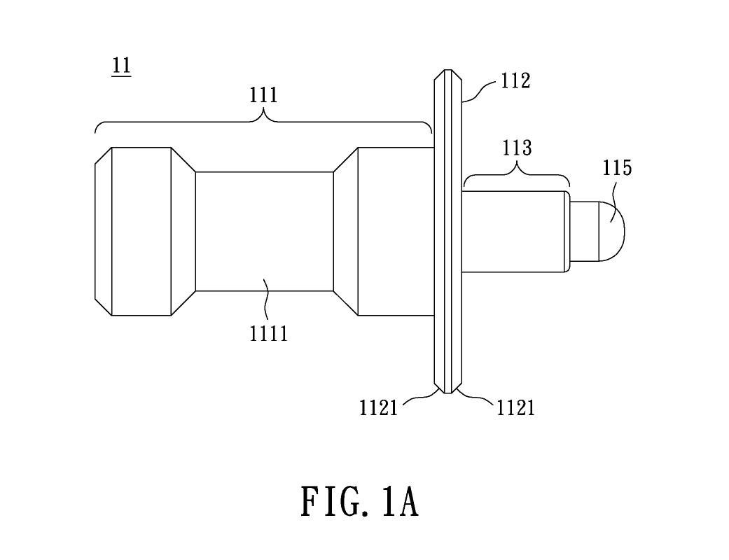

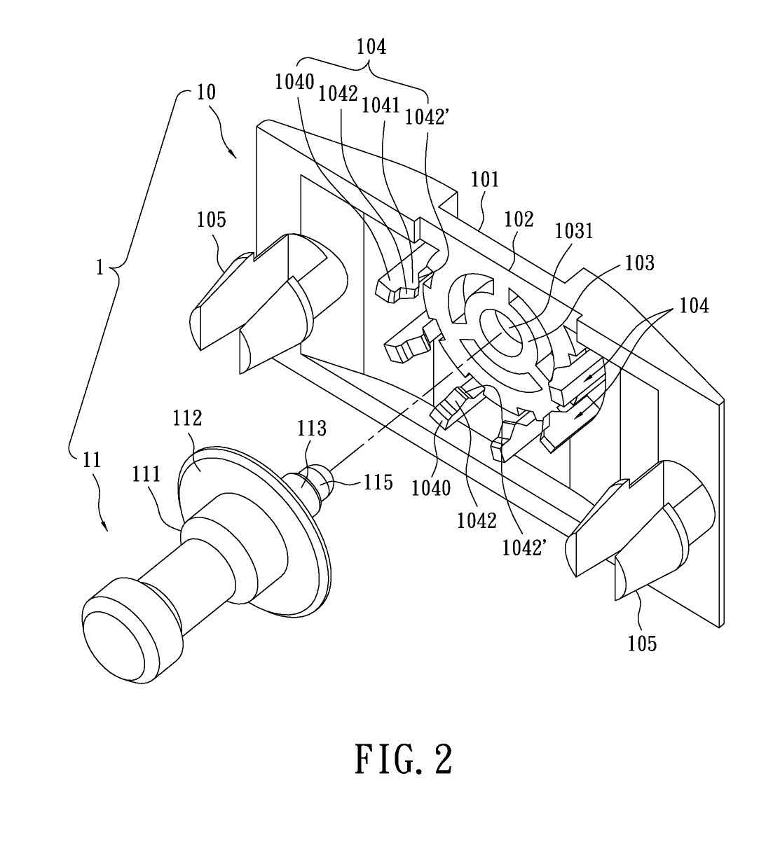

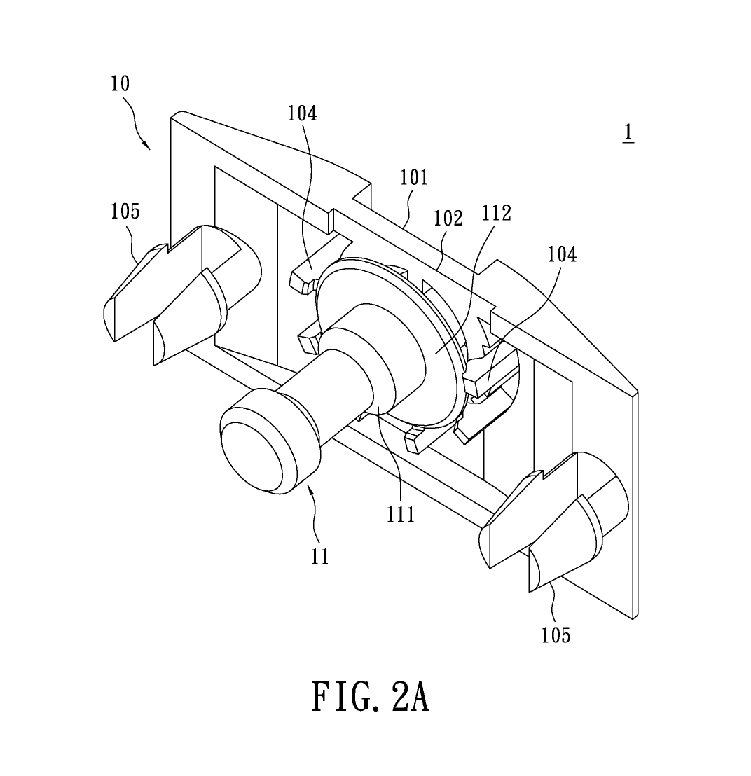

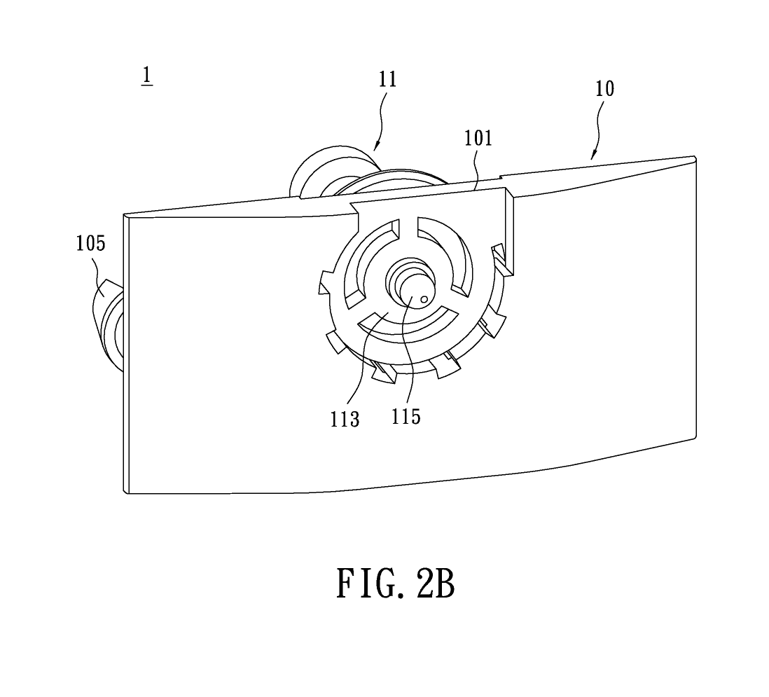

As shown in FIGS. 1 to 2B, FIG. 1 is a perspective view of the fixing plate of the fixing unit in the first embodiment of the instant disclosure, FIG. 1A shows the bolting member of the fixing unit in the first embodiment of the instant disclosure, FIG. 2 is an explode diagram of the fixing unit in the first embodiment of the instant disclosure, FIG. 2A is a perspective view of the combination of the fixing plate and the bolting member in FIG. 2, and FIG. 2B is another perspective view of the combination of the fixing plate and the bolting member in FIG. 2 at a view angle.

Please refer to FIGS. 1 and 1A which respectively shows each of the two major components of a fixing unit in accordance with the instant disclosure. Specifically, an exemplary fixing unit 1 comprises a fixing plate 10 (as shown in FIG. 1) and a bolting member 11 (as shown in FIG. 1A). The assembling detail of the fixing plate 10 and the bolting member 11 is shown in FIGS. 2, 2A and 2B.

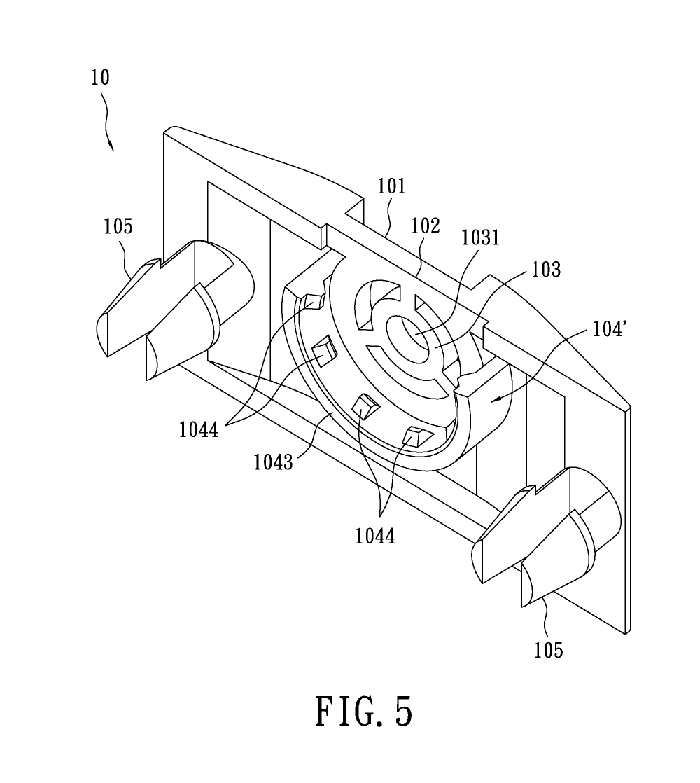

As shown in FIG. 1, the fixing plate 10 is a plate structure, which is preferably made of resilient materials having sufficient structural strength and deformability, such as plastic. The bolting member 11 can be removably coupled to the fixing plate 10 for fixing/releasing a computer accessory device to/from the frame of a computer casing. The fixing plate 10 is constructed with a predetermined thickness that is sufficient to maintain proper structural strength. The fixing plate 10 has a front surface 101 and a rear surface 102 opposite to the front surface 101. The fixing plate 10 has a holding portion 103 arranged on the plate surface thereof. Preferably, the holding portion 103 is engraved on the fixing plate 10. The holding portion 103 defines a guiding hole through which part of the bolting member 11 may be inserted. The instant exemplary fixing plate 10 utilizes a circular-shaped holding portion 103 that defines a circular through hole (i.e., the guiding hole) 1031. However, the holding portion 103 can be of shapes other than a circular ring. For example, the holding portion 103 can be ellipse-shaped, circular-shaped, or even polygonal shaped, as aesthetically or operationally required. The through hole 1031 is formed from the front surface 101 to the rear surface 102 so that portions of the bolting member 11 can be inserted there-through. The fixing plate 10 preferably has a concave structure correspondingly formed on the front surface 101 corresponding to the holding portion 103 to receive the following-mentioned protruding segment 115 which protrudes out of the front surface 101. While the computer accessory device is not in the locked position (i.e., in the original position or the unlocked position), the protruded protruding segment 115 can be “hide” in the concave structure and does not interfere with the computer accessory device. In addition, the fixing plate 10 has a locking structure 104 formed on the rear surface 102 thereof. The locking structure 104 can have various structures which are used to lock or release the bolting member 11. FIG. 1 shows the first embodiment of the fixing plate 10. In the exemplary embodiment, the locking structure 104 includes a plurality of pillars 1040 formed on the rear surface 102. The pillars 1040 substantially surround the periphery of the holding portion 103. Each pillar 1040 has a protruded portion 1041 and the protruded portion 1041 has two corresponding first guiding inclines 1042, 1042′. Accordingly, the protruded portion 1041 can be used to lock or release the bolting member 11 because of the flexibility of the pillars 1040. Please refer to FIG. 5; another exemplary embodiment of the fixing plate 10 is shown. The locking structure 104′ includes an annular plate 1043 formed on the rear surface 102. The annular plate 1043 has a plurality of blocking projections 1044 thereon. Each blocking projection 1044 is structurally and functionally similar with the protruded portion 1041 of the first embodiment. In other words, the blocking projection 1044 may has two corresponding first guiding inclines. Similarly, the blocking projection 1044 can be used to lock or release the bolting member 11 because of the flexibility of the annular plate 1043. Hereinafter, the usage of the bolting member 11 and the locking structure 104 shown in FIG. 1 will be described in further detail.

As shown in FIG. 1A; the bolting member 11 has a substantially elongated pillar or a substantially columnar body, on which a main segment 111, an extension segment 113, and a protruding segment 115 are sequentially defined. The bolting member 11 further includes a first flanged structure 112 arranged between the main segment 111 and the extension segment 113. The first flanged structure 112 is correspondingly designed to be slidable into the position defined between the protruded portion 1041 (or the blocking protrusion 1044) of the locking structure 104 and the rear surface 102 of the fixing plate 10, thus allowing a retaining engagement to be established between the bolting member 11 and the fixing plate 10. The main segment 111, the extension segment 113 and the protruding segment 115 have different diameters (i.e., the outer diameters). For example, in the instant exemplary embodiment, the diameter of the protruding segment 115 is less than that of the extension segment 113, and the diameter of the extension segment 113 is less than that of the main segment 111. Furthermore, the outer diameter of the extension segment 113 is slightly less than the inner diameter of the holding portion 103 (i.e., the diameter of the through hole 1031). The instant exemplary embodiment illustrates the first flanged structure 112 having a planar rim configuration and second guiding inclines 1121. In addition, the main segment 111 of the bolting member 11 further has a concave holding portion 1111, so as to make a user operate the bolting member 11 easily. However, the exact arrangement and the configuration of the main segment 111, the extension segment 113, the protruding segment 115 and the first flanged structure 112 are not limited to the exemplary embodiment, so long as they meet the requirements of being adaptably coupleable with the fixing plate 10 to establish detachable retaining engagement with the locking structure 104.

Similar to the fixing plate 10, the bolting member 11 is preferably made of materials having sufficient resilience, such as plastic. While assembling the bolting member 11 onto the fixing plate 10, the protruding segment 115 with smallest diameter is first inserted into the through hole 1031 of the holding portion 103 and then the extension segment 113 is pushed through the holding portion 103. After assembling, the first flanged structure 112 abuts against the first guiding inclines 1042 of the locking structure 104, as shown in FIGS. 2 to 2B.

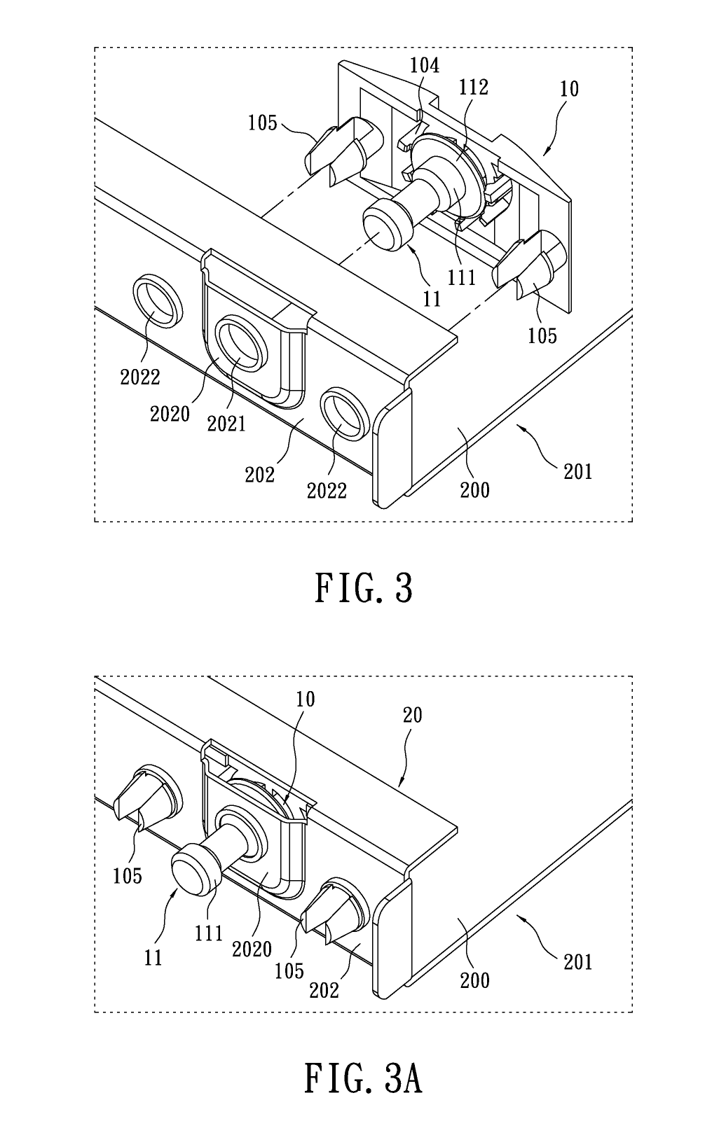

The fixing plate 10 further has a plurality of attaching members 105 formed on the rear surface 102. The attaching members 105 may be used to secure the fixing plate 10 on the computer accessory device mounting member 20, as shown in FIGS. 3 and 3A.

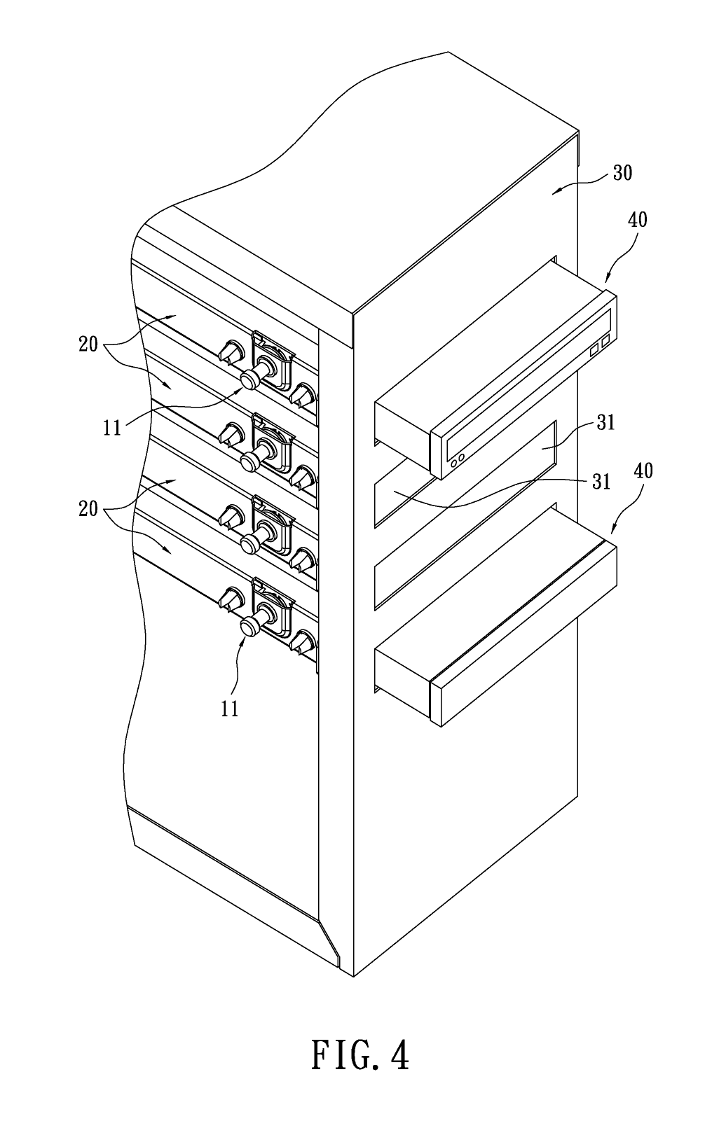

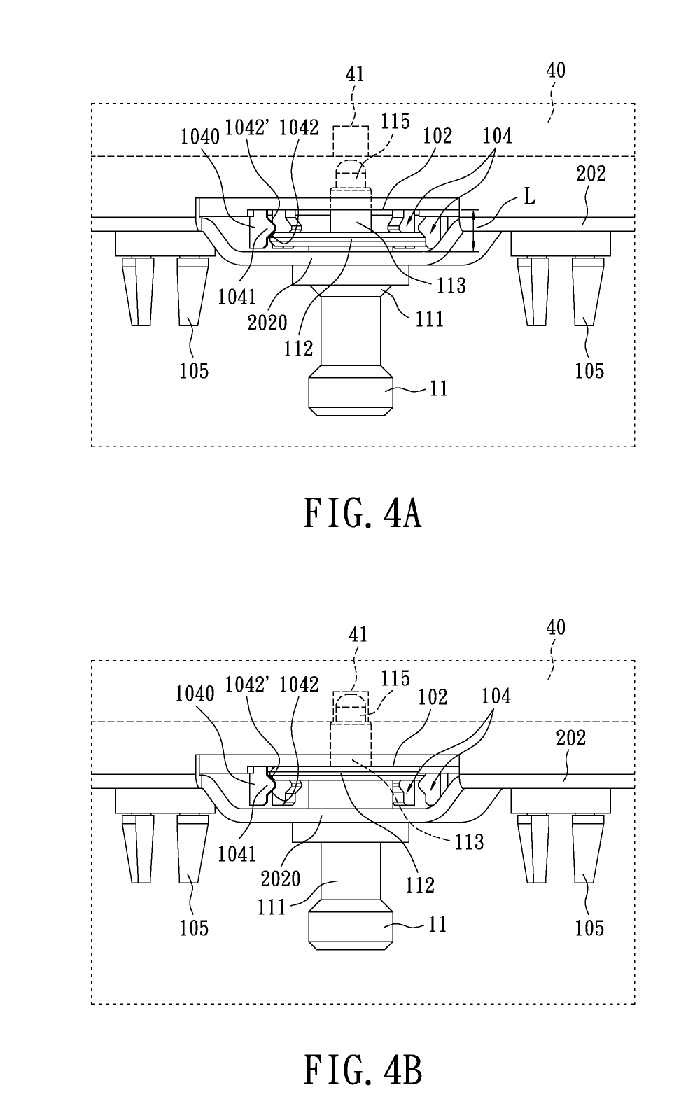

Please refer to FIG. 3, which is an explode diagram of the computer accessory device mounting member 20 and the fixing unit 1 in the first embodiment of the instant disclosure. The fixing unit 1 can be assembled on a computer accessory device mounting member 20 of a computer casing to serve as a disk drive retainer. It is noted that the computer accessory device mounting member 20 may utilize one or more fixing unit 1, and the exact placement location of the fixing unit 1 is not limited to the exemplary illustrations shown in the instant figures. The fixing unit 1 and the computer accessory device mounting member 20 are constructed a computer accessory device mounting apparatus. The computer accessory device mounting member 20 may be made of metal materials and defines an accommodating space 200 for carrying a computer accessory device 40, such as hard disk drive, floppy disk drive, optic disk drive or electric card reader, as shown in FIGS. 3A and 4. In the exemplary embodiment, the computer accessory device mounting member 20 includes a bottom plate 201 and a plurality of side plates 202 to cooperatively define a component accommodating space 200. Depending on particularly operational requirement, one or more fixing unit 1 can be assembled on the desired side plate 202. In further detail, the side plate 202 may have a convex side edge 2020, so that the interior surface of the side edge 2020 is at a distance “L” (referred as a movement distance), as shown in FIG. 4A, from the rear surface 102 of the fixing member 10. Furthermore, an insertion hole 2021 is formed on the top surface of the side edge 2020 and the concave holding portion 1111 is exposed out of the insertion hole 2020 of the computer accessory device mounting member 20. As a result, the bolting member 11 is hold in the insertion hole 2021 and the movement of the bolting member 11 is limited within the gap “L”. Moreover, the side plate 202 further has assembling holes 2022. As shown in FIG. 3A, while the fixing plate 10 is fixedly secured on the computer accessory device mounting member 20 by inserting the attaching members 105 into the assembling holes 2022, the main segment 111 of the bolting member 11 may be movably inserted through the insertion hole 2021 of the computer accessory device mounting member 20 and exposed beyond the top surface of the side plate 202. Users can force on the main segment 111 to push or pull the bolting member 11 to lock/release the locking structure 104. Moreover, when the fixing unit 1 is assembled on the computer accessory device mounting member 20, the first flanged structure 112 is limited by the insertion hole 2021 because of the lager outer diameter of the first flanged structure 112 so that the bolting member 11 may not drop from the computer accessory device mounting member 20. It is noted that the assembling of the fixing plate 10 and the computer accessory device mounting member 20 may be not restricted by the attaching members 105 and the assembling holes 2022.

Please refer to FIG. 4; the assembled fixing unit 1 and computer accessory device mounting member 20 may be installed inside an electronic device. The electronic device at least has a casing 30 which has an opening 31 communicating with the interior of the casing 30. The opening 31 corresponds to the accommodating space 200 so that the computer accessory device 40 can be mounted inside the casing 30 through the opening 31. In other words, users may insert the computer accessory device 40 and then fix it on the computer accessory device mounting member 20 inside the casing 30. Furthermore, the computer accessory device 40 has at least one retaining hole 41 defined in a sidewall thereof corresponding to the insertion hole 2021. The corresponding bolting member 11 is pushed or pressed to a locked position so that the protruding segment 115 can be inserted into and interfered with the retaining hole 41 to lock the computer accessory device 40. On the contrary, users can pull out the bolting member 11 for releasing the insertion of the protruding segment 115 in the retaining hole 41 of computer accessory device 40. Therefore; the computer accessory device 40 is capable for drawing out of the casing 30.

As further shown in FIG. 4A, that is an enlarged top sectional view of the computer accessory device mounting apparatus and the computer accessory device in an unlocked position. The bolting member 11 is at an original position (i.e., a unlocked position). In the original position, the first flanged structure 112 of the bolting member 11 is not limited and restricted by the locking structure 104. In other words, the first flanged structure 112 is located between the protruded portion 1041 of the locking structure 104 and the inner surface of the side edge 2020, and the protruding segment 115 does not interfere with the retaining hole 41 of the computer accessory device 40. For locking the computer accessory device 40, users can force on the main segment 111 to push in the bolting member 11 at a fixing position (i.e., a locked position). While forcing the bolting member 11, the protruding segment 115 is moved toward the retaining hole 41 until the first flanged structure 112 is passed over the protruded portion 1041 and limited by the other first guiding inclines 1042′ of the locking structure 104. During the second guiding incline 1121 of the first flanged structure 112 contacting and moving with respect to the first guiding inclines 1042 of the protruded portion 1041, the pillars 1040 are deformed by the movement of the first flanged structure 112. Until the first flanged structure 112 moving to the position between the protruded portion 1041 of the locking structure 104 and the rear surface 102, the pillars 1040 restore to the initial state due to its elastic property.. Simultaneously, the protruding segment 115 moves toward and then inserts into the retaining hole 41 of the computer accessory device 40. Thus, in the locked position, the computer accessory device 40 is fixed and locked in the computer accessory device mounting member 20 by the fixing unit 1 as shown in FIG. 4B.

On the other hand, when users want to draw the computer accessory device 40 out of the casing 30, users may exert force on the main segment 111 to pull out the protruding segment 115 from the retaining hole 41. While forcing the bolting member 11 to move in a reverse direction, the second guiding incline 1121 of the first flanged structure 112 is contacted and moved with respect to the first guiding inclines 1042′ of the protruded portion 1041, the pillars 1040 are deformed by the movement of the first flanged structure 112 elastically. Until the first flanged structure 112 back to the unlocked position. Meanwhile, the protruding segment 115 does not interfere with the retaining hole 41 of the computer accessory device 40 (as shown in FIG. 4A) and users can draw the computer accessory device 40 out of the casing 30.

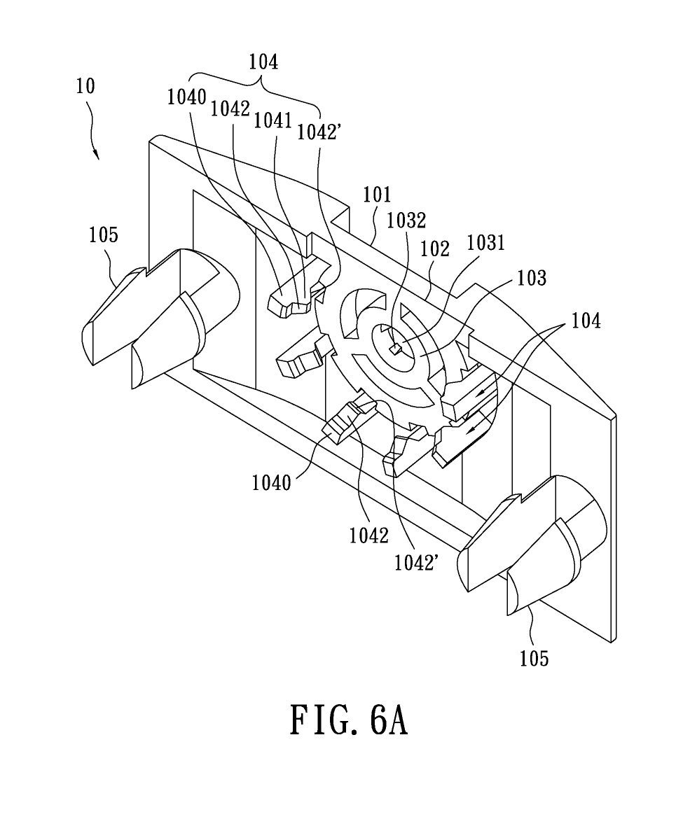

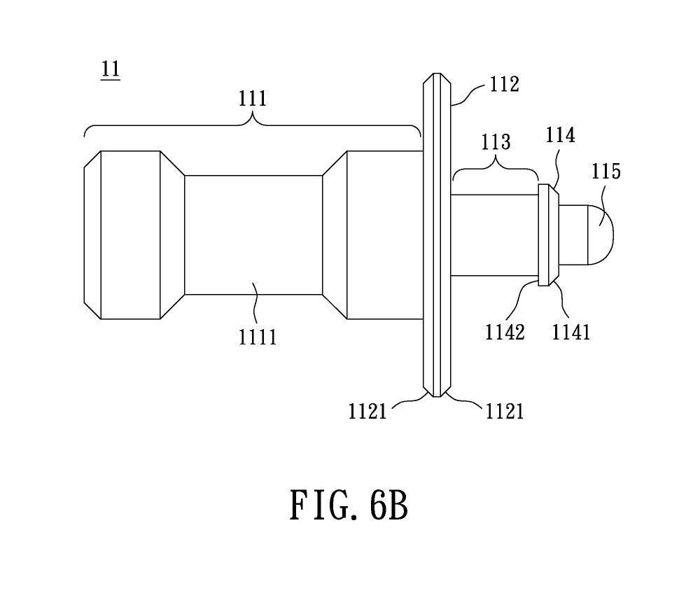

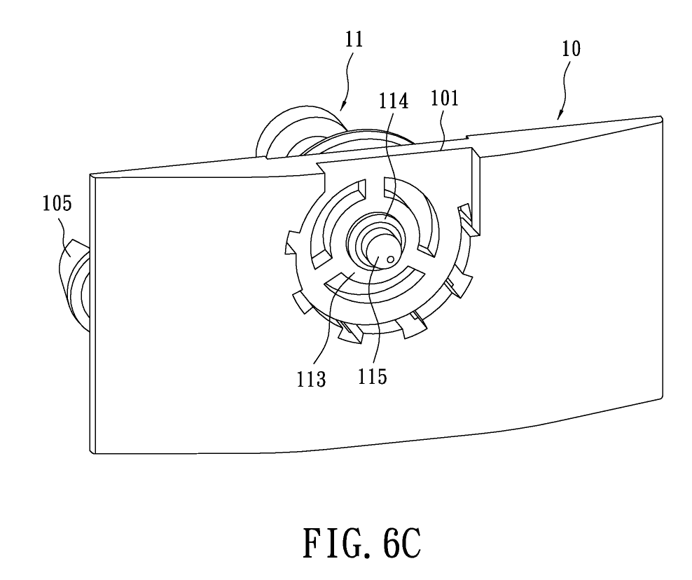

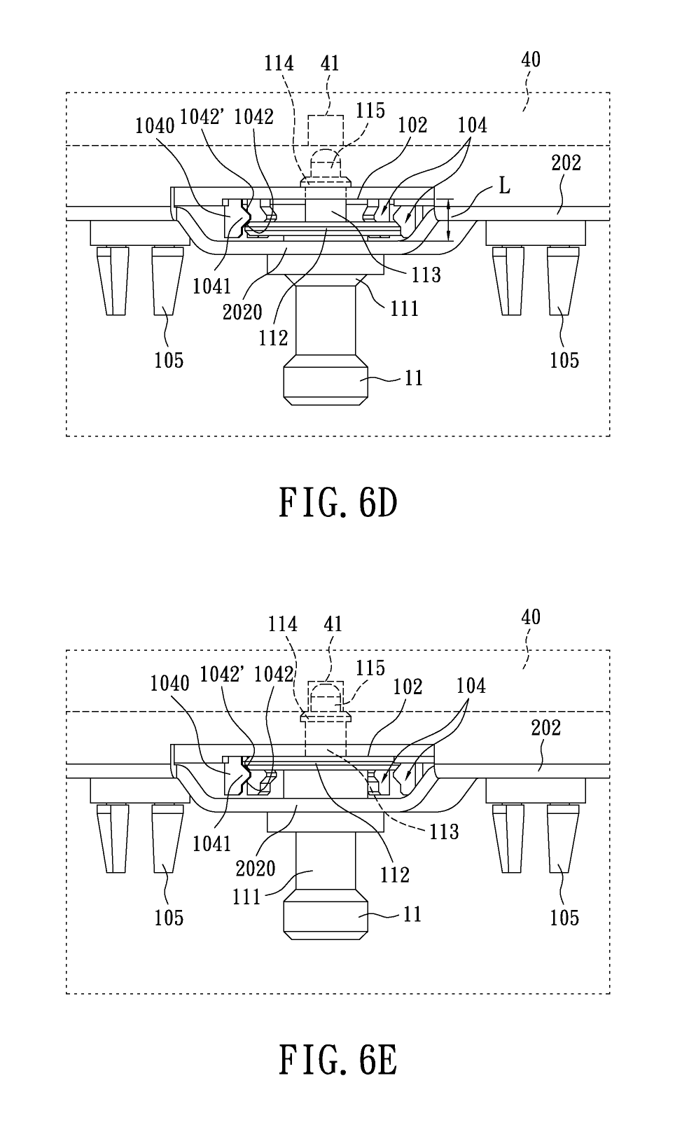

A second exemplary embodiment of the instant disclosure is shown in FIGS. 6A to 6E. Please refer to FIG. 6A, a plurality of retarding projections 1032 are radially arranged along the inner circumference of the holding portion 103. Preferably, each retarding projection 1032 has a guiding inclined surface defined thereon. As shown in FIG. 6B, the bolting member 11 includes a main segment 111, an extension segment 113 and a protruding segment 115 connected to the extension segment 113. The bolting member 11 further has a first flanged structure 112 and a second flanged structure 114. The first flanged structure 112 is located between the main segment 111 and the extension segment 113, and the first flanged structure 112 corresponds to the locking structure 104. The second flanged structure 114 is located between the extension segment 113 and the protruding segment 115, and the second flanged structure 114 corresponds to the holding portion 103. Similar to the first embodiment, the main segment 111, the extension segment 113 and the protruding segment 115 have different diameters (i.e., the outer diameters), such as the diameter of the protruding segment 115 is less than that of the extension segment 113, and the diameter of the extension segment 113 is less than that of the main segment 111. Furthermore, the outer diameter of the extension segment 113 is slightly less than the inner diameter of the holding portion 103 (i.e., the diameter of the through hole 1031). In addition, the outer diameter of the second flanged structure 114 is slightly larger than the inner diameter of the holding portion 103.

Similar to the first embodiment, the bolting member 11 may be preferably made of materials having sufficient resilience, such as plastic. While assembling the bolting member 11 on the fixing plate 10, the protruding segment 115 with smallest diameter is first inserted into the through hole 1031 of the holding portion 103 and then the second flanged structure 114 is pushed through the holding portion 103. The front side of the second flanged structure 114 preferably has an auxiliary guiding incline 1141, and the rear side of the second flanged structure 114 has a blocking surface 1142. The guiding inclined surface defined on the retarding projection 1032 corresponds to the auxiliary guiding incline 1141. While forcing the bolting member 11 to move, the auxiliary guiding incline 1141 may slide on the guiding inclined surface of the retarding projections 1032 in the inner surface of the through hole 1031; then, due to the elastic property of the holding portion 103, the second flanged structure 114 may pass through the holding portion 103. Because of the diameter difference and the blocking surface 1142 preferably formed on the rear side of the second flanged structure 114, the second flanged structure 114 is limited to move back by the holding portion 103. Therefore, the bolting member 11 is movably fixed on the fixing plate 10. In other words, the bolting member 11 is stably connected to the fixing plate 10 and the lost issue of the traditional screws/bolts can be solved, even when the fixing unit 1 of the present invention does not applied on fixing the computer accessory device 40. After forcing the second flanged structure 114 through the holding portion 103, the retarding projections 1032 formed on the inner surface of the holding portion 103 may interfere with the blocking surface 1142 of the second flanged structure 114; thus, it is more difficult for the assembled bolting member 11 to release from the fixing plate 10.

Please refer to FIG. 6D, which is an enlarged top view of the computer accessory device mounting member having the fixing unit of FIG. 6C and the computer accessory device in an unlocked position. The bolting member 11 is at an original position (i.e., an unlocked position). In the original position, the second flanged structure 114 of the bolting member 11 merely hangs on the holding portion 103 and the first flanged structure 112 of the bolting member 11 is kept in place by the protruded portion 1041 on the computer accessory device mounting member 20 without engaging with the locking structure 104. In other words, the first flanged structure 112 of the bolting member 11 is retained between the protruded portion 1041 of the locking structure 104 and the inner surface of the side edge 2020, and the protruding segment 115 does not interfere with the retaining hole 41 of the computer accessory device 40. For locking the computer accessory device 40, users can exert force on the main segment 111 to push in the bolting member 11 at a fixing position (i.e., a locked position). While forcing the bolting member 11 to move, the protruding segment 115 is moved toward the retaining hole 41 until the first flanged structure 112 is passed over the protruded portion 1041 and limited by the other first guiding inclines 1042′ of the locking structure 104. During the second guiding incline 1121 of the first flanged structure 112 contacting and moving with respect to the first guiding inclines 1042 of the protruded portion 1041, the pillars 1040 are deformed by the movement of the first flanged structure 112 and resilient due to the elastic property. Thus, the first flanged structure 112 moves to the position between the protruded portion 1041 of the locking structure 104 and the rear surface 102. Simultaneously, the protruding segment 115 moves toward and then inserts in the retaining hole 41 of the computer accessory device 40. Thus, in the fixing position, the computer accessory device 40 is fixed and locked in the computer accessory device mounting member 20 by the fixing unit 1 as shown in FIG. 6E.

On the contrary, when users want to draw the computer accessory device 40 out of the casing 30, users may exert force on the main segment 111 to pull out the bolting member 11. While forcing the bolting member 11 to move in a reverse direction, the second guiding incline 1121 of the first flanged structure 112 is contacted and moved with respect to the first guiding inclines 1042′ of the protruded portion 1041; then, the pillars 1040 are deformed by the movement of the first flanged structure 112 elastically. Thus, the first flanged structure 112 may move back to the position of between the protruded portion 1041 of the locking structure 104 and the inner surface of the side edge 2020 (i.e., the original position or the unlocked position). Meanwhile, the protruding segment 115 does not insert into or interfere with the retaining hole 41 of the computer accessory device 40 (as shown in FIG. 6D) and users can draw the computer accessory device 40 out of the casing 30. It is noted that the blocking surface 1142 of the second flanged structure 114 may be limited by the retarding projections 1032 formed on the inner surface of the holding portion 103.

Therefore, the first flanged structure 112 can be forced to move between the gap “L” defined between the rear surface 102 of the fixing plate 10 and the interior surface of the side edge 2020 to control the position of the protruding segment 115. Furthermore, the protruded portion 1041 located in the gap “L” may be applied to “switch” the locked state and the unlocked state of the computer accessory device 40.

On the other hand, the second flanged structure 114 of the bolting member 11 is limited to move backward by the holding portion 103, after the second flanged structure 114 passed through the holding portion 103. Therefore, the bolting member 11 is stably connected to the fixing plate 10 and the lost issue can be solved, even when the fixing unit 1 of the present invention does not applied on fixing the computer accessory device 40.

According to the second exemplary embodiment, a first-level assembling of the bolting member 11 and the fixing plate 10 is achieved by the second flanged structure 114 of the bolting member 11 and the holding portion 103 of the fixing plate 10. The first-level assembling of the bolting member 11 and the fixing plate 10 may to be applied to keep the bolting member 11 on the fixing plate 10. A second-level assembling of the bolting member 11 and the fixing plate 10 is achieved by the first flanged structure 112 and the locking structure 104. The second-level assembling of the bolting member 11 and the fixing plate 10 may to be applied to insert the protruding segment 115 into the retaining hole 41 of the computer accessory device 40 and then fixing the computer accessory device 40 onto the casing 30 of the electronic device.

To sum up, the present invention at least has the following characteristics.

1. The fixing unit of the present invention is friendly to use. The non-convenience of using screws and tools for assembling/disassembling the computer accessory device can be solved. In other words, the assembling of computer accessory device is more efficiently.

2. The first-level assembling in the present invention may keep the bolting member on the fixing plate; therefore, the traditional lost issue can be solved. Users can force on the bolting member to push in/pull out the bolting member to lock/release the computer accessory device. Thus, the computer accessory device can be efficiently assembled or disassembled with the casing.

The description above only illustrates specific embodiments and examples of the present invention. The present invention should therefore cover various modifications and variations made to the herein-described structure and operations of the present invention, provided they fall within the scope of the present invention as defined in the following appended claims.

What is claimed is:

1. A fixing unit comprising:
a fixing plate having a front surface and a rear surface, the fixing plate having a holding portion arranged thereon defining a guiding hole, and a locking structure formed on the rear surface correspondingly around the holding portion; and
a bolting member engageable with the locking structure from the rear surface of the fixing plate, the bolting member having a main segment, an extension segment and a protruding segment sequentially defined thereon,
wherein the protruding segment is insertable into the guiding hole,
wherein a first flanged structure is arranged between the main segment and the extension segment correspondingly engageable with the locking structure, and
wherein when the bolting member is secured to the fixing plate, the protruding segment of the bolting member at least partially exposes from the front surface.

2. The fixing unit as claimed in claim 1, wherein the bolting member is substantially columnar body and further comprises a second flanged structure arranged between the extension segment and the protruding segment, wherein the inner surface of the holding portion has a plurality of retarding projections formed exsertedly thereon, a front side of the second flanged structure has an auxiliary guiding incline, a rear side of the second flanged structure has a blocking surface, and each retarding projection has a guiding inclined surface defined thereon corresponding to the auxiliary guiding incline.

3. The fixing unit as claimed in claim 1, wherein the locking structure includes a plurality of pillars formed on the rear surface, the pillars substantially surround the periphery of the holding portion, each of the pillars has a protruded portion, the protruded portion has two corresponding first guiding inclines, the edge of the first flanged structure has two second guiding inclines corresponding to the first guiding inclines.

4. The fixing unit as claimed in claim 1, wherein the locking structure includes an annular plate formed on the rear surface, the annular plate has a plurality of blocking projections, each of the blocking projections has two corresponding first guiding inclines, the edge of the first flanged structure has two second guiding inclines corresponding to the first guiding inclines.

5. The fixing unit as claimed in claim 1, wherein the fixing plate further comprises a plurality of attaching members formed on the rear surface.

6. The fixing unit as claimed in claim 1, wherein the main segment further has a concave holding portion.

7. A computer accessory device mounting apparatus for fixing a computer accessory device having at least one retaining hole on a side wall thereof, the computer accessory device mounting apparatus comprising:
a computer accessory device mounting member defining an accommodating space therein, wherein the computer accessory device mounting member has an insertion hole on a side edge thereof, and the insertion hole corresponds to the retaining hole; and
a fixing unit fixed on the computer accessory device mounting member correspondingly to the side edge of the computer accessory device mounting member, the fixing unit including:
a fixing plate fixed on the computer accessory device mounting member, the fixing plate having a front surface and a rear surface, the fixing plate having a holding portion arranged thereon defining a guiding hole, and a locking structure formed on the rear surface thereof; and
a bolting member movably assembled on the rear surface of the fixing plate, wherein the bolting member includes a main segment movably inserted through the insertion hole, an extension segment and a protruding segment sequentially defined thereon;
wherein a first flanged structure is arranged between the main segment and the extension segment correspondingly engageable with the locking structure, the extension segment inserts into the holding portion, and
wherein when the bolting member is secured to the fixing plate, the protruding segment of the bolting member exposes from the front surface and corresponds to the retaining hole of the computer accessory device.

8. The computer accessory device mounting apparatus as claimed in claim 7, wherein the bolting member is substantially columnar body and further comprises a second flanged structure between the extension segment and protruding segment, the inner surface of the holding portion has a plurality of retarding projections formed exsertedly thereon, a front side of the second flanged structure has an auxiliary guiding incline, a rear side of the second flanged structure has a blocking surface, and each retarding projection has a guiding inclined surface defined thereon corresponding to the auxiliary guiding incline.

9. The computer accessory device mounting apparatus as claimed in claim 7, wherein the locking structure includes a plurality of pillars formed on the rear surface, the pillars substantially surround the periphery of the holding portion, each of the pillars has a protruded portion, the protruded portion has two corresponding first guiding inclines, the edge of the first flanged structure has two second guiding inclines corresponding to the first guiding inclines.

10. The computer accessory device mounting apparatus as claimed in claim 7, wherein the locking structure includes an annular plate formed on the rear surface, the annular plate has a plurality of blocking projections, each of the blocking projections has two corresponding first guiding inclines, the edge of the first flanged structure has two second guiding inclines corresponding to the first guiding inclines.

11. The computer accessory device mounting apparatus as claimed in claim 7, wherein the rear surface of the fixing plate and the interior surface of the side edge of the computer accessory device mounting member have a gap therebetween, the first flanged structure moves inside the gap.

12. The computer accessory device mounting apparatus as claimed in claim 7, wherein the fixing plate further comprises a plurality of attaching members formed on the rear surface, the computer accessory device mounting member has a plurality of assembling holes corresponding to the attaching members.

13. The computer accessory device mounting apparatus as claimed in claim 7, wherein the main segment of the bolting member further has a concave holding portion, the concave holding portion is exposed out of the insertion hole of the computer accessory device mounting member.

14. An electronic device, comprising:
a casing having an opening communicating with the interior of the casing;
at least one computer accessory device mounting apparatus disposed in the interior of the casing, the computer accessory device mounting apparatus being used for fixing a computer accessory device having at least one retaining hole on a side wall thereof, the computer accessory device mounting apparatus comprising:
a computer accessory device mounting member defining an accommodating space corresponding to the opening, wherein the computer accessory device mounting member has an insertion hole on a side edge thereof, and the insertion hole corresponds to the retaining hole; and
a fixing unit fixed on the computer accessory device mounting member correspondingly to the side edge of the computer accessory device mounting member, the fixing unit including:
a fixing plate fixed on the computer accessory device mounting member, the fixing plate having a front surface and a rear surface, the fixing plate having a holding portion arranged thereon defining a guiding hole, and a locking structure formed on the rear surface thereof; and
a bolting member movably assembled on the rear surface of the fixing plate, wherein the bolting member includes a main segment movably inserted through the insertion hole, an extension segment and a protruding segment sequentially defined thereon;
wherein a first flanged structure is arranged between the main segment and the extension segment correspondingly engageable with the locking structure, the extension segment inserts into the holding portion, and
wherein when the bolting member is secured to the fixing plate, the protruding segment of the bolting member exposes from the front surface and corresponds to the retaining hole of the computer accessory device.

15. The electronic device as claimed in claim 14, wherein the bolting member further comprising a second flanged structure between the extension segment and protruding segment, the inner surface of the holding portion has a plurality of retarding projections formed exsertedly thereon, a front side of the second flanged structure has an auxiliary guiding incline, a rear side of the second flanged structure has a blocking surface, and each retarding projection has a guiding inclined surface defined thereon corresponding to the auxiliary guiding incline.

16. The electronic device as claimed in claim 14, wherein the locking structure includes a plurality of pillars formed on the rear surface, the pillars substantially surround the periphery of the holding portion, each of the pillars has a protruded portion, the protruded portion has two corresponding first guiding inclines, the edge of the first flanged structure has two second guiding inclines corresponding to the first guiding inclines.

17. The electronic device as claimed in claim 14, wherein the locking structure includes an annular plate formed on the rear surface, the annular plate has a plurality of blocking projections, each of the blocking projections has two corresponding first guiding inclines, the edge of the first flanged structure has two second guiding inclines corresponding to the first guiding inclines.

18. The electronic device as claimed in claim 14, wherein the rear surface of the fixing plate and the interior surface of the side edge of the computer accessory device mounting member have a gap therebetween, the first flanged structure moves inside the gap.

19. The electronic device as claimed in claim 14, wherein the fixing plate further comprises a plurality of attaching members formed on the rear surface, the computer accessory device mounting member has a plurality of assembling holes corresponding to the attaching members.

20. The electronic device as claimed in claim 14, wherein the main segment of the bolting member further has a concave holding portion, the concave holding portion is exposed out of the insertion hole of the computer accessory device mounting member.
